(19) United States
(12) Patent Application Publication
(10) Pub. No.: US 2009/0320912 A1
(43) Pub. Date: Dec. 31, 2009

(54) Component with a Structured Layer on a Carrier Substrate

(75) Inventors: Ulrich Schindler, Furth/Bayern (DE); Christoph Brabec, Linz (AT)

Correspondence Address: HOFFMANN & BARON, LLP, 6900 JERICHO TURNPIKE, SYOSSET, NY, 11791, US

(73) Assignees: KONARKA Technologies, Inc., Lowell, MA (US); LEONHARD KURZ STIFTUNG & CO., KG, Furth (DE)

(21) Appl. No.: 12/227,964

(22) PCT Filed: Jun. 6, 2007
(86) PCT No.: PCT/EP2007/005017

§ 371 Date: Jan. 28, 2009

(30) Foreign Application Priority Data
Jun. 10, 2006 (DE) 10 2006 026 981.0

(51) Int. Cl. H01L 31/00; C04B 35/00; B05D 5/12

(52) U.S. Cl. 136/254; 136/256; 264/104; 427/75

(57) ABSTRACT

Described is a component with a sharp-edgedly structured layer comprising at least one highly fluid low-viscosity medium (20) having a given solids content on a carrier substrate (10), wherein a boundary layer (14) defining the outside contour of the structured layer is provided on the carrier substrate (10) and the at least one low-viscosity highly fluid medium (20) is provided at the inside surface (18) of the carrier substrate (10), which inside surface is defined by the boundary layer (14).

The invention concerns a component with a structured layer comprising a highly fluid, low-viscosity medium having a given solids content on a carrier substrate.

The at least one highly fluid low-viscosity medium can be a paint or lacquer, a dye or a suspension. Such a medium can for example consist of pigments, a binding agent and a solvent and may optionally have additives. Highly fluid low-viscosity media may also only be solutions of organic media or polymers; they generally have a low solids content.

The problem which arises with highly fluid low-viscosity media is that they have a tendency to undesirably run or run together on a carrier substrate and are therefore difficult to work, that is to say use in printing, in comparison with conventional dyes or lacquers.

By way of example, in the production of polymer-based solar cells, highly fluid low-viscosity media with a low solids content have to be processed, to produce suitable structured layers. Those layers are produced for example in a printing process.

The object of the invention is to provide a component of the kind set forth in the opening part of this specification, in which respect it is easily possible to produce a structured layer comprising at least one highly fluid low-viscosity medium on a carrier substrate in accurate contour relationship.

That object is attained by a component with a structured layer comprising at least one highly fluid, low-viscosity medium having a given solids content on a carrier substrate, wherein provided on the carrier substrate is a boundary layer defining the outside contour of the structured layer and the at least one low-viscosity highly fluid medium is provided at the inside surface of the carrier substrate, said inside surface being defined by the boundary layer.

In the component according to the invention it is also possible for a plurality of low-viscosity highly fluid media to be provided in mutually juxtaposed relationship, in which case a respective drying operation can be carried out therebetween.

The boundary layer on the one hand prevents the at least one highly fluid low-viscosity medium from running so that it is possible to produce a layer which is structured with accurate contours from the at least one highly fluid low-viscosity medium.

In accordance with a preferred embodiment of the invention the boundary layer or one or more subregions of the boundary have a further additional optical, electrical and/or mechanical functionality. The boundary layer further has for example a functionality like that of a registration line, an electrical contact, an external contacting region, a region for producing visual effects, a light scattering reason for further coupling in light, as adhesive regions or contacting regions for adhesive layers and also as an insulation line for structuring lines of electrodes.

The boundary structure afforded by the boundary layer or a plurality of boundary layers can thus also be used as a registration line. If for example at least one of the low-viscosity highly fluid media is a colorless medium which is not visible to the naked eye after drying and which has to be printed in a previously defined region, then application of one or more media in accurate register relationship can be ensured by means of the boundary structure in the form of a registration line.

In addition the boundary structure can also be used in such a way that it not only affords a definition boundary for low-viscosity highly fluid media but it also provides an electrically insulating region for interrupting conductive regions, such as for example electrodes consisting for example of ITO or IMI.

The boundary structure or one or more subregions of the boundary structure can additionally also comprise an electrically conductive material and form contacting elements of the component. They can thus be provided in the external regions as external contacting regions, for example as external contacts (bus bar) of the component for the contacting of electrical systems.

In this connection the boundary structure or a subregion of the boundary structure—insofar as it comprises a conductive system, such as for example a system with Ag or carbon (‘carbon black’)—can also serve as a contacting region or regions or a possible way of affording electrical contacting and can provide a corresponding function in the component.

If the situation involves a suitable selection in respect of the composition of the boundary structure, it can also afford optical and visual effects. Thus it is possible for example for the boundary structure or a subregion of the boundary structure to comprise a medium containing optically variable pigments or to include luminescent substances. Furthermore it is possible for the boundary structure to be of such a configuration that—in the case of photovoltaics—a light scattering action is effected by way thereof, and that results in an increase in the light coupling-in effect into the active regions of the cell, for example light is additionally coupled into the photoactive layer of the component.

The boundary layer can be applied to the carrier substrate with the respectively desired edge contour, that is to say straight, curved or of any other configuration, by printing, embossing or lamination. A screen printing operation, intaglio printing, flexoprinting or the like can be used as the printing process. By way of example a hot embossing process can be used as the embossing process. Application of the at least one highly fluid low-viscosity medium to the inside surface of the carrier substrate, which is suitably delimited by the boundary layer which is constructed as desired, can be effected in any per se known manner. By way of example the at least one highly fluid low-viscosity medium is applied by screen printing to the inside surface of the carrier substrate, that is delimited by the boundary layer.

Investigations have shown that the selection of the composition of the material of the boundary structure and thus the surface energy formed (after drying of the boundary structure) can greatly influence wetting of the subsequent layers, in the region of the boundary structure. It has proven to be advantageous in that respect for the surface energy of the boundary structure (after drying) to be selected to be higher than that of the medium, or vice-versa. That makes it possible to achieve a good wetting action.

In accordance with a further preferred embodiment of the invention application of the boundary structure or structures is preceded by a preliminary treatment operation or operations on the carrier. In that respect, plasma treatment, corona treatment, wet-chemical treatment and so forth can be effected as the preliminary treatment. The preliminary treatment operation or operations is or are in that respect to be so selected that it or they does not or do not lead to any detrimental effects on the functional layers.

The carrier substrate can involve a plate-shaped carrier substrate which is stable in respect of shape or a flexible flat film material in strip or web form.

In accordance with a preferred embodiment of the invention the wall thickness of the boundary layer is inversely proportional to the solids content of the highly fluid medium so that the material consumption for the boundary layer is advantageously limited to a minimum. In that connection, a boundary structure of a wall thickness of 3.5 μm has been found to be advantageous for producing a 200 nm dry semiconductor layer, formed from a 6% solution.

If the boundary layer is applied to the carrier substrate by printing, a material is used for the boundary layer, having a viscosity which is printable in accurate contour relationship.

At least one boundary layer which is straight, of a wave-like configuration or shaped in any other fashion, in frame form, can be provided on the carrier substrate, and thereafter the at least one low-viscosity medium can be provided thereon. This involves a process for the production of a virtually discontinuous boundary layer which is structured in accurate contour relationship on a carrier substrate. Another possibility provides the provision on a flexible carrier body of strip shape, of at least one pair of boundary layers which extend in the longitudinal direction of the strip and which are line-shaped in a straight line, in a wavy configuration, curved or the like, with the at least one low-viscosity medium being provided therebetween. This involves a process for the production of a virtually continuous boundary layer which is structured in accurate contour relationship, on a carrier substrate.

With the component according to the invention, to produce polymer-based solar cells, the at least one low-viscosity highly fluid medium can be a polymer electronic medium of P3HAT, PCBM (poly-3-hexylthiophene and fullerenes) or a mixture of P3HT and PCBM which for example can have two or more mutually superposed medium layers. If a plurality of low-viscosity media are used it is possible to use one and the same boundary layer, but the wall thickness must then be suitably adapted.

In accordance with the invention the boundary layer may be a sacrificial layer which is removable from the carrier body after drying of the at least one low-viscosity medium if the boundary layer or structures do not have one of the above-mentioned further functionalities.

Further details, features and advantages will be apparent from the description hereinafter of variants diagrammatically illustrated in the drawing of processes for the production of a component according to the invention with a structured layer comprising at least one highly fluid low-viscosity medium on a carrier substrate.

In the drawing:

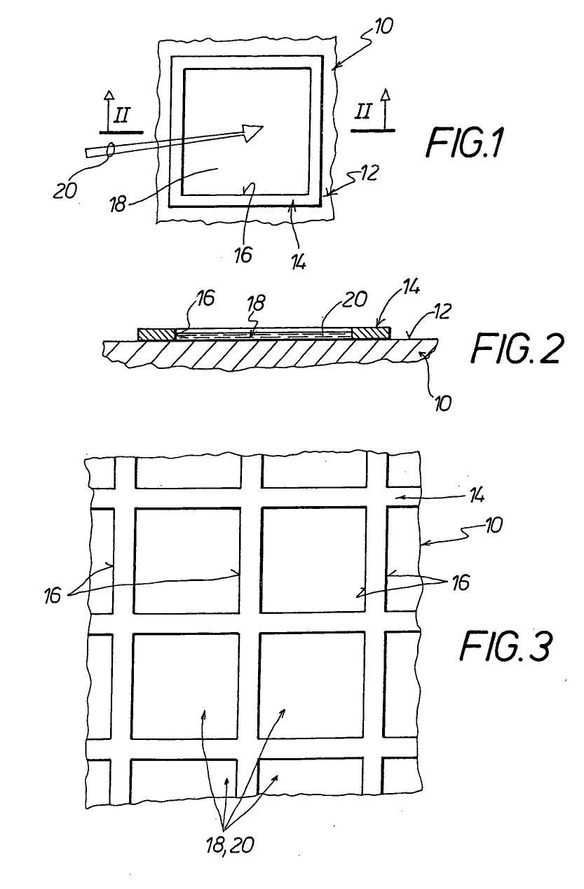

FIG. 1 shows a plan view of a portion of a first variant of the process for the production of a component according to the invention,

FIG. 2 shows a section along section line II-II in FIG. 1,

FIG. 3 shows a plan view of a portion similar to FIG. 1 of a second variant of the process,

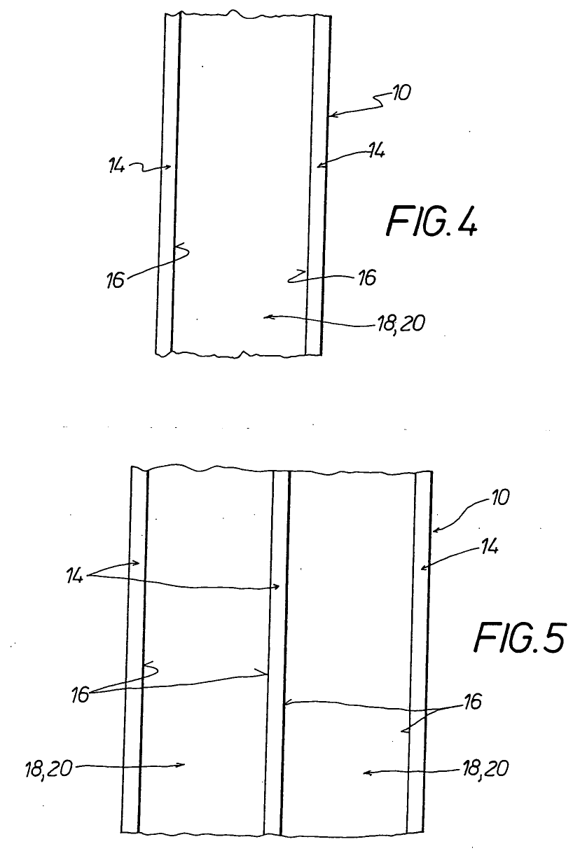

FIG. 4 shows a plan view of a portion similar to FIGS. 1 and 3 of a third variant of the process, and

FIG. 5 shows a view similar to FIG. 4 of a fourth variant of a process for the production of a component according to the invention.

FIGS. 1 and 2 show a portion of a carrier substrate 10 having a surface 12, to which a boundary layer 14 is applied in a first process step. The boundary layer 14 is of a frame-shaped configuration and has a sharp-edged inside contour 16. In this case the boundary structure, besides the further functionality of the registration line, does not have any further functionalities as were discussed hereinbefore.

After application of the frame-shaped boundary layer 14 at least one highly fluid low-viscosity medium is applied to the inside surface 18 of the carrier substrate 10, which is delimited by the boundary layer 14. This is symbolically indicated by the arrow 20 in FIG. 1. That process step can be selectively repeated a plurality of times—also using different media. The at least one low-viscosity medium 20 is for example a polymer electronic medium in order to produce polymer-based solar cells with the process according to the invention.

While FIG. 1 only shows one single frame-shaped boundary layer 14 on the surface 12 of the carrier substrate 10, FIG. 3 shows a portion of a carrier substrate 10, to the surface 12 of which is applied a grid-like boundary layer 14 to produce a corresponding number of inside surfaces 18 to which the at least one low-viscosity medium 20 is then applied to embody a corresponding number of solar cells. Here too the layer only involves the functionality of providing a boundary and the functionality of providing the registration line; further functionalities are in this case ignored and are not considered.

FIG. 4 shows a portion of a flexible carrier substrate 10 in strip form, which is provided at each of its two longitudinal edges with a respective line-shaped boundary layer and registration line 14. Further functionalities of the boundary lines are not considered in FIG. 4.

The line-shaped boundary and registration layers 14 each have a sharp-edged inside contour 16. At least one low-viscosity highly fluid medium is applied to the carrier substrate 10 at the inside surface 18 defined by the inside contours 16, between the two line-shaped boundary and registration layers 14. That can be effected for example by means of intaglio roller printing.

FIG. 5 shows a plan view similar to FIG. 4 illustrating a portion of a carrier substrate 10 which is not only provided at each of its two longitudinal edges with a respective line-shaped boundary layer 14 but also with a further boundary layer 14 in a central region of the carrier substrate 10 in strip form. The boundary layers 14 define two inside surfaces 18, at each of which there is provided at least one respective highly fluid low-viscosity medium 20. In this case also the boundary layer has only one further functionality, that of a registration line—further functionalities are not considered in this case by way of example.

The boundary layer 14—irrespective of its respective form—prevents the at least one highly fluid low-viscosity medium 20 from running on the surface 12 of the carrier substrate 10.

FIGS. 1 through 5 each show straight-lined structures for the boundary layers 14. It will be appreciated that the boundary layers 14 can also be formed with other edge contours which correspond to the respective demands involved.

1-18. (canceled)

19. A component with a structured layer comprising at least one highly fluid, low-viscosity medium having a given solids content on a carrier substrate, wherein, provided on the carrier substrate, is a boundary layer defining the outside contour of the structured layer and the at least one low-viscosity highly fluid medium is provided at the inside surface of the carrier substrate, said inside surface being defined by the boundary layer, wherein the boundary layer or one or more subregions of the boundary layer form registration lines for application in accurate register relationship of the at least one medium in predefined regions of the carrier substrate and/or form a light scattering region for coupling in light and/or form an adhesive region and/or form contacting regions for an adhesive layer.

20. A component as set forth in claim 19, wherein the wall thickness of the boundary layer is inversely proportional to the solids content of the highly fluid medium.

21. A component as set forth in claim 20, wherein the wall thickness of the boundary layer is 3.5 μm and the highly fluid medium for forming the structured layer in the form of a 200 nm thick dry semiconductor layer is a 6% solution.

22. A component as set forth in claim 19, wherein the boundary layer is of a grid-shaped configuration.

23. A component as set forth in claim 19, wherein the boundary layer is of a frame-shaped configuration.

24. A component as set forth in claim 19, wherein, provided on a flexible carrier substrate in strip form, is at least one pair of line-shaped boundary layers extending in the longitudinal direction of the strip and provided between the boundary layers is the at least one low-viscosity highly fluid medium.

25. A component as set forth in claim 19, wherein the boundary layers forms registration lines.

26. A component as set forth in claim 19, wherein the boundary layer or subregions of the boundary layer comprises an electrically conductive material and is in the form of an electrical contacting element for contacting regions of the component, that are to be contacted.

27. A component as set forth in claim 19, wherein the boundary layer is in the form of an electrical external contact.

28. A component as set forth in claim 19, wherein the boundary layer includes optically variable pigments or luminescent substances.

29. A component as set forth in claim 19, wherein the component is a polymer-based solar cell.

30. A component as set forth in claim 29, wherein the boundary layer is in the form of a scattering region for coupling light into a photoactive region of the solar cell.

31. A component as set forth in claim 19, wherein the boundary layer is in the form of an adhesive region or in the form of a contacting region for an adhesive layer.

32. A component as set forth in claim 19, wherein the boundary layer is in the form of an insulating region between two electrically conductive or semiconducting regions of the component.

33. A component as set forth in claim 29, wherein the at least one low-viscosity highly fluid medium is a polymer electronic medium.

34. A component as set forth in claim 19, wherein the boundary layer is a sacrificial layer removable from the carrier substrate after drying of the at least one low-viscosity highly fluid medium.

35. A process for the production of a component as set forth in claim 19, wherein the boundary layer is applied to the carrier substrate by printing or embossing or lamination.

36. A process for the production of a component as set forth in claim 35, wherein the boundary layer is applied to the carrier substrate by embossing means of a hot embossing process.
